(19) United States
(12) Patent Application Publication
(10) Pub. No.: US 2002/0141524 A1
(43) Pub. Date: Oct. 3, 2002

(54) Multiphase serializer

(75) Inventor: David William Boerstler, Round Rock, TX (US)

Correspondence Address: Kelly K. Kordzik, 100 Congress Avenue, Suite 800, Austin, TX, 78701, US

(73) Assignee: International Business Machines Corporation

(21) Appl. No.: 09/820,506

(22) Filed: Mar. 29, 2001

(51) Int. Cl. H03M 9/00; H04L 7/00; H04L 25/00; H04L 25/40

(52) U.S. Cl. 375/371

(57) ABSTRACT

A system, transmitter and method for serializing parallel data. A system may comprise a transmitter configured to transmit serial data to a receiver through a transmission medium, e.g., wireless, wired. The transmitter may comprise a first input configured to receive N bits of parallel data. The transmitter may further comprise a second input configured to receive M phases of a clock operating at a frequency lower than the data rate of the serial data. The transmitter may further comprise a serializer coupled to the first and second input. The serializer may be configured to generate a plurality of slices of a serial form of the parallel data using the M phases of a clock. Upon generating the plurality of slices, the serializer may be configured to combine the plurality of slices generated to produce the serial data.

### CROSS REFERENCE TO RELATED APPLICATIONS

The present invention is related to the following U.S. patent applications which are incorporated herein by reference:

Ser. No. ______ (Attorney Docket No. AUS920000511US1) entitled “Synchronization State Detector” filed ______.

Ser. No. ______ (Attorney Docket No. AUS920000512US1) entitled “Multiphase Retiming Mechanism” filed ______.

### TECHNICAL FIELD

The present invention relates to the field of digital transmission, and more particularly to serializing data by using multiple phases of a clock operating at a frequency lower than the data rate.

### BACKGROUND INFORMATION

As electronic and computer technology continues to evolve, communication of information among different devices, either situated near by or at a distance becomes increasingly important. It is now more desirable than ever to provide high speed communications among different chips on a circuit board, different circuit boards in a system and different systems with each other. It is also desirable to provide high speed communications in intensive data consuming systems using graphical or video information, multiple input-output channels, local area networks, etc.

Data may be transmitted between different devices in a communication system through a data link. Typically, data is transmitted in parallel whenever possible in order to increase bandwidth. However, due to cost, weight, interference (noise) and electrical loading considerations, parallel transmission is not feasible in many systems. In order to simplify the communications problem, data may be transmitted serially. By transmitting data serially, less hardware is required for the actual communications link between the different devices. However, parallel data must be converted to serial form for the transmission.

A serializer may be used in a communication system to convert parallel data to a serial form. Typically, a serializer converts the parallel data to a serial form using a phase-locked loop oscillator operating at the transmission rate, i.e., serial data rate. By the phase-locked loop oscillator operating at a frequency equivalent to the transmission rate, i.e., serial data rate, instead of at a frequency lower than the transmission rate, i.e., serial data rate, a significant amount of power may be used.

Therefore, there is a need in the art to serialize data in a manner that requires less power.

### SUMMARY

The problems outlined above may at least in part be solved in some embodiments by serializing parallel data using multiple phases of a phase clock operating at a frequency lower than the serial data rate.

In one embodiment, a system comprises a transmitter configured to transmit serial data to a receiver through a transmission medium, e.g., wireless, wired. The transmitter may comprise a first input configured to receive N bits of parallel data. The transmitter may further comprise a second input configured to receive M phases of a phase clock operating at a frequency lower than the serial data rate. When one edge of the M phases of the phase clock are used to convert the parallel data to serial data, the phase clock operates at a frequency of 1/N of the serial data rate. When both edges of the M phases of the phase clock are used to convert the parallel data to serial data, the phase clock operates at a frequency of 1/(2*N) of the serial data rate. The transmitter may further comprise a serializer coupled to the first and second input. The serializer may be configured to generate a plurality of slices of a serial form of the parallel data using the M phases of a phase clock. A slice may refer to a section or segment of the serial data. Upon generating the plurality of slices, the serializer may be configured to combine the plurality of slices generated to produce the serial data.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

A better understanding of the present invention can be obtained when the following detailed description is considered in conjunction with the following drawings, in which:

FIG. 1 illustrates an embodiment of the present invention of a serial data link;

FIG. 2 illustrates an embodiment of a transmitter in a serial data link configured in accordance with the present invention;

FIG. 3 illustrates an embodiment of the present invention of a serializer;

FIG. 4 illustrates an embodiment of a subsystem of a serializer configured in accordance with the present invention;

FIGS. 5A-5C is a timing diagram illustrating the timing of each phase of a clock, each bit of the parallel data and the serial data according to the present invention;

FIGS. 6A-C is a timing diagram illustrating the timing of the first phase of a clock, the first bit in the parallel data and the first slice of serial data produced by a first subsystem according to the present invention;

FIGS. 7A-C is a timing diagram illustrating the timing of the second phase of a clock, the second bit in the parallel data and the second slice of serial data produced by a second subsystem according to the present invention;

FIGS. 8A-C is a timing diagram illustrating the timing of the third phase of a clock, the third bit in the parallel data and the third slice of serial data produced by a third subsystem according to the present invention;

FIGS. 9A-C is a timing diagram illustrating the timing of the fourth phase of a clock, the fourth bit in the parallel data and the fourth slice of serial data produced by a fourth subsystem according to the present invention;

FIGS. 10A-C is a timing diagram illustrating the timing of the fifth phase of a clock, the fifth bit in the parallel data and the fifth slice of serial data produced by a fifth subsystem according to the present invention;

FIGS. 11A-F is a timing diagram illustrating the timing of each slice output of the subsystems and the serial data produced by the subsystems according to the present invention; and

FIG. 12 is a flowchart of a method for serializing parallel data.

### DETAILED DESCRIPTION

The present invention comprises a system, transmitter and method for serializing parallel data. In one embodiment of the present invention, a system comprises a transmitter configured to transmit serial data to a receiver through a transmission medium, e.g., wireless, wired. The transmitter may comprise a first input configured to receive N bits of parallel data. The transmitter may further comprise a second input configured to receive M phases of a phase clock operating at a frequency lower than the serial data rate. When one edge of the M phases of the phase clock are used to convert the parallel data to serial data, the phase clock operates at a frequency of 1/N of the serial data rate. When both edges of the M phases of the phase clock are used to convert the parallel data to serial data, the phase clock operates at a frequency of 1/(2*N) of the serial data rate. The transmitter may further comprise a serializer coupled to the first and second input. The serializer may be configured to generate a plurality of slices of a serial form of the parallel data using the M phases of a phase clock. A slice may refer to a section or segment of the serial data. Upon generating the plurality of slices, the serializer may be configured to combine the plurality of slices generated to produce the serial data.

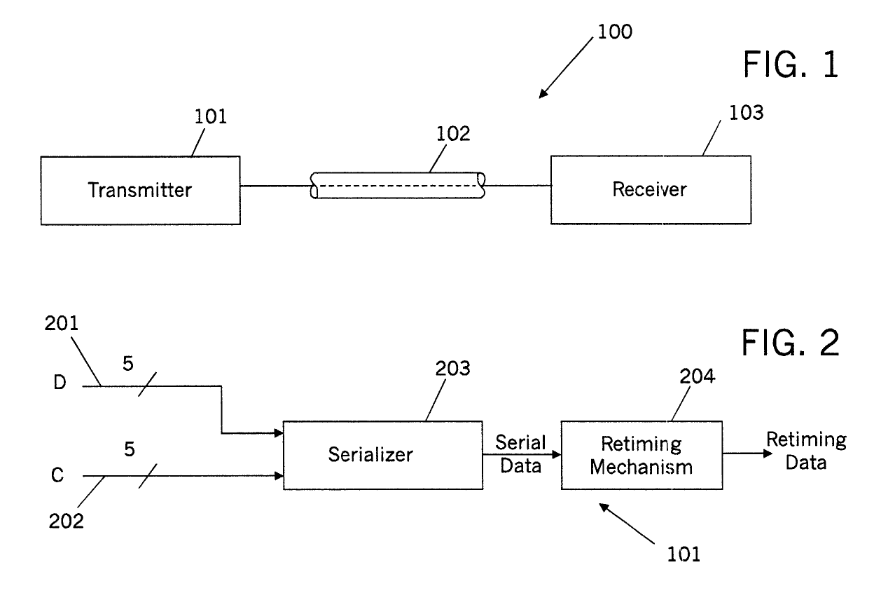

FIG. 1—Serial Data Link

FIG. 1 illustrates an embodiment of the present invention of a serial data link 100 used in a communication system. As stated in the Background Information, data may typically be transmitted between various devices in a communication system through a “data link”. Typically, data is transmitted in parallel whenever possible in order to increase bandwidth. However, due to cost, weight, interference (noise) and electrical loading considerations, parallel transmission is not feasible in many systems. In order to simplify the communications problem, data may be transmitted serially across a serial data link 100 by a transmitter 101. Transmitter 101 may be configured to convert the parallel data to a serial form which may be transmitted through a medium 102, e.g., wired, wireless, to a receiver 103 configured to convert the serial data into parallel form which may then be transmitted to another device, e.g., computer, cellular phone.

FIG. 2—Transmitter

FIG. 2 illustrates an embodiment of the present invention of a transmitter 101 configured to convert parallel data to a serial form. Transmitter 101 may comprise a serializer 203 configured to convert N bits of parallel data 201 into a serial form using M phases of a phase clock 202 at a frequency lower than the serial data rate. The serial data signal generated by serializer 203 may exhibit timing uncertainties as the result of interference, attenuation, skin effect, etc. These timing uncertainties are commonly referred to as “jitter.” “Jitter” may refer to an offset of time as to when the serial data signal transitions from a high to a low state or from a low to a high state. It may be desirable but necessary to reduce these timing uncertainties by retiming the serial data signal by a retiming mechanism 204. Retiming mechanism 204 may be configured to diminish these timing uncertainties by sampling the serial data signal at points in time when the serial data signal is not likely to experience jitter, e.g., sampling during the middle of a period of the serial data signal. The output of retiming mechanism 204 is the retimed data where the retimed data is the data after sampling the serial data signal at points in time when the serial data signal is not likely to experience jitter. In one embodiment, the number of phases of clock 202 is the same number as the number of bits in parallel data 201 when one edge of clock 202 is used to convert parallel data 201 into a serial form. When the number of phases of clock 202 is the same number as the number of bits in parallel data 201, clock 202 operates at a frequency of 1/(number of bits of parallel data 201) times the serial data rate which corresponds to the data rate of parallel data 201. In the exemplary embodiment of transmitter 101, serializer 203 may convert five bits of parallel data 201 using five phases of clock 202. In the exemplary embodiment, parallel data 201 has a data rate of 1 gigabits per second. Since there are five bits of parallel data 201 in the exemplary embodiment, clock 202 has a frequency of ⅕ of the serial data rate which corresponds to the data rate of parallel data 201 which equals 1 gigabits per second. Since clock 202 operates at a frequency of 1 gigahertz in the exemplary embodiment, each phase of clock 202 has a period of 1000 picoseconds in the exemplary embodiment. Subsequently, each phase is asserted 200 picoseconds after the previous phase. In another embodiment, the number of phases of clock 202 is one half the number of bits in parallel data 201 when both edges of the phases of clock 202 are used to convert parallel data 201 into a serial form. When the number of phases of clock 202 is one half the number of bits in parallel data 201, clock 202 operates at a frequency of 1/(2*number of bits of parallel data 201) times the serial data rate. It is noted that parallel data 201 may operate at any data rate. It is further noted that since clock 202 may have any number of phases, clock 202 may operate at any frequency lower than the serial data rate thereby saving power.

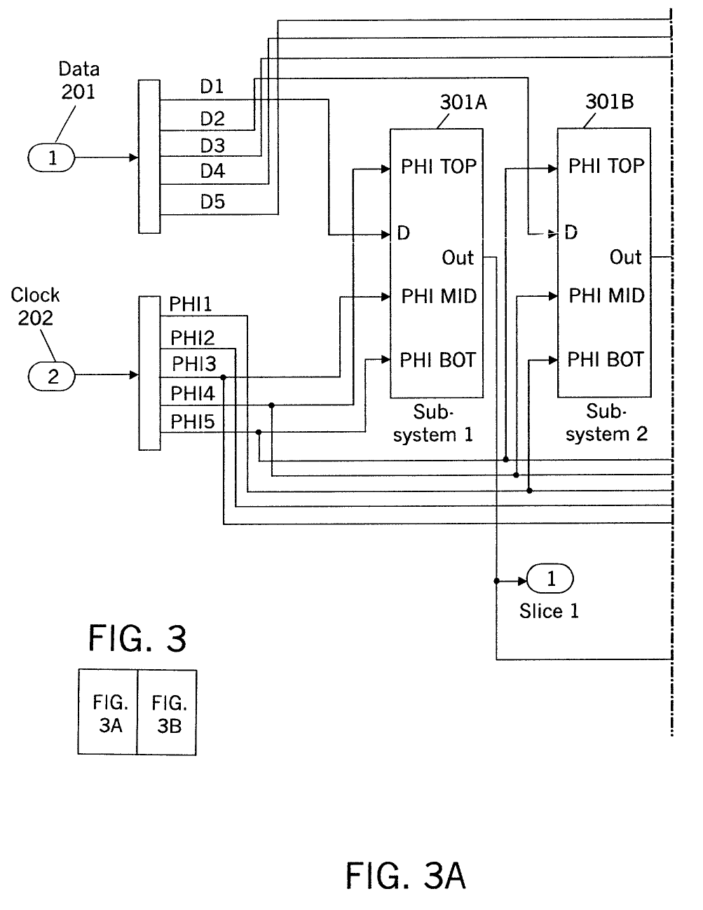

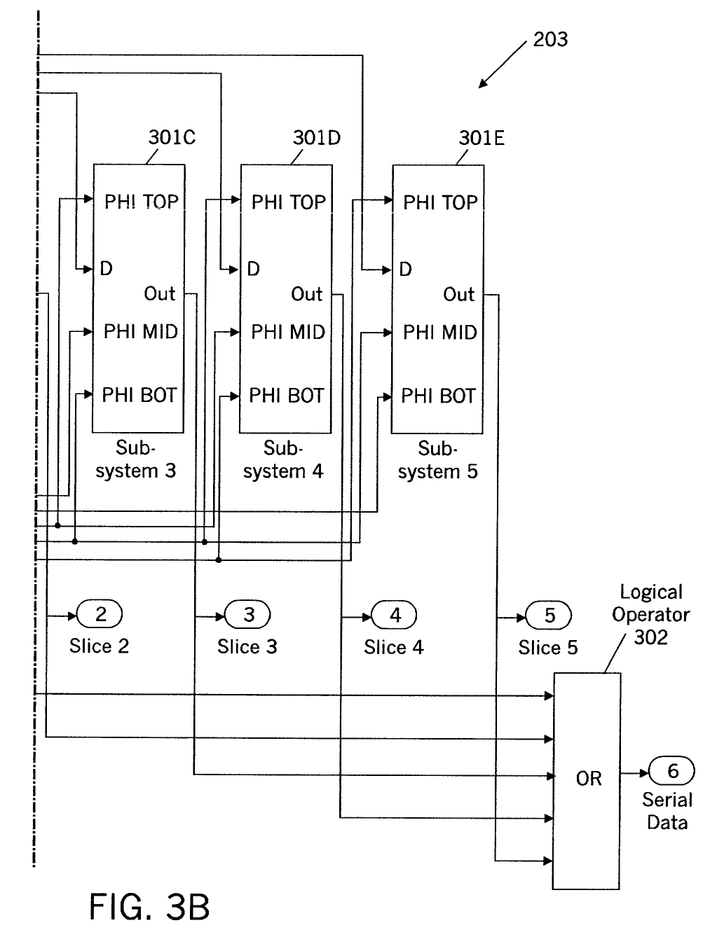

FIG. 3—Serializer

FIG. 3 illustrates an embodiment of the present invention of a serializer 203. As stated above, serializer 203 may be configured to convert the N bits, e.g., five bits, of parallel data 201 represented as D1, D2, D3, D4, D5 to a serial form using the M phases, e.g., five phases, represented as PHI1, PHI2, PHI3, PHI4, PHI5 of clock 202 in the exemplary embodiment. Serializer 203 may comprise a plurality of subsystems 301A-E configured to generate a plurality of “slices” of serial data as described in greater detail below. Subsystems 301A-E may collectively or individually be referred to as subsystems 301 or subsystem 301, respectively. Serializer 203 may further comprise a logical OR gate 302 that performs the logical OR operation on slice(s) of serial data generated by each subsystem 301. A slice may refer to a section or segment of serial data.

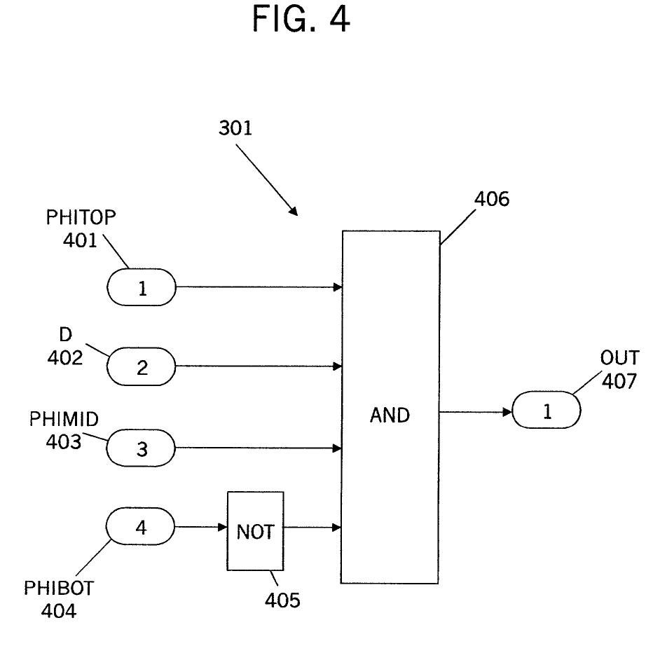

Each subsystem 301 may be configured to logically AND three phases of clock 202 and a particular bit in parallel data 201 as illustrated in FIG. 4. FIG. 4 illustrates an embodiment of the present invention of subsystem 301 comprising a logical AND gate 406 that performs the AND operation on a particular bit in parallel data 201 as well as on three of the five phases of clock 202 that are inputted to subsystem 301, e.g., PHI TOP 401, PHI MID 403, PHI BOT 404. The logical state of the phase of clock 202 inputted to PHI BOT 404 of subsystem 301 may be inverted by a logical NOT gate 405. The output of subsystem 301 is one or more slices of serial data.

Each particular subsystem 301, e.g., 301A-E, performs a logical AND operation on a different set of inputs, e.g., three of the five phases of clock 202 and a particular bit in parallel data 201. For example, subsystem 301A performs the logical AND operation on PHI4, D1, PHI3 and PHI5′ where the ′ after PHI5 indicates that the logical state of PHI5 has been inverted in accordance with the embodiments in FIGS. 3 and 4. Similarly, subsystem 301B performs the logical AND operation on PHI5, D2, PHI4 and PHI1′ where the ′ after PHI1 indicates that the logical state of PHI1 has been inverted. Subsystem 301C performs the logical AND operation on PHI1, D3, PHI5 and PHI2′ where the ′ after PHI2 indicates that the logical state of PHI2 has been inverted. Subsystem 301D performs the logical AND operation on PHI2, D4, PHI1 and PHI3′ where the ′ after PHI3 indicates that the logical state of PHI3 has been inverted. Subsystem 301E performs the logical AND operation on PHI3, D5, PHI2 and PHI4′ where the ′ after PHI4 indicates that the logical state of PHI4 has been inverted.

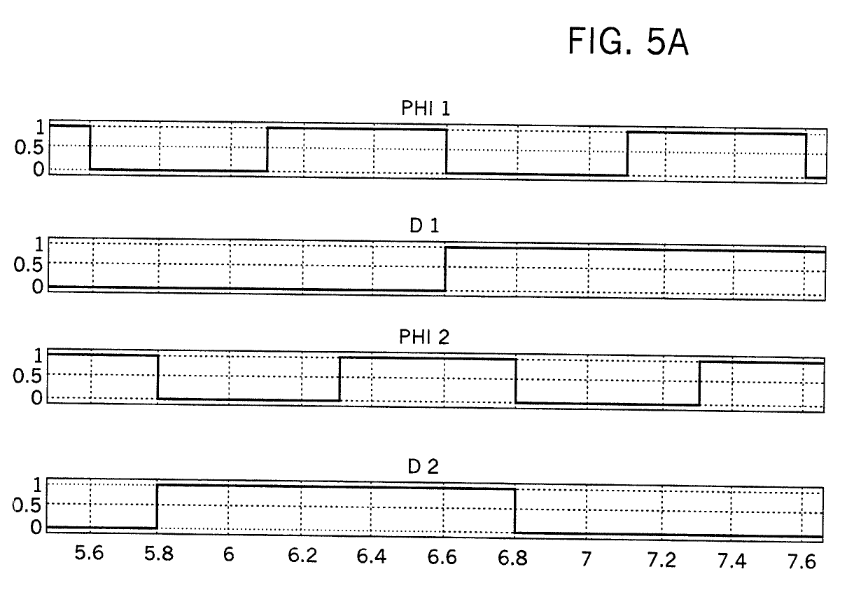

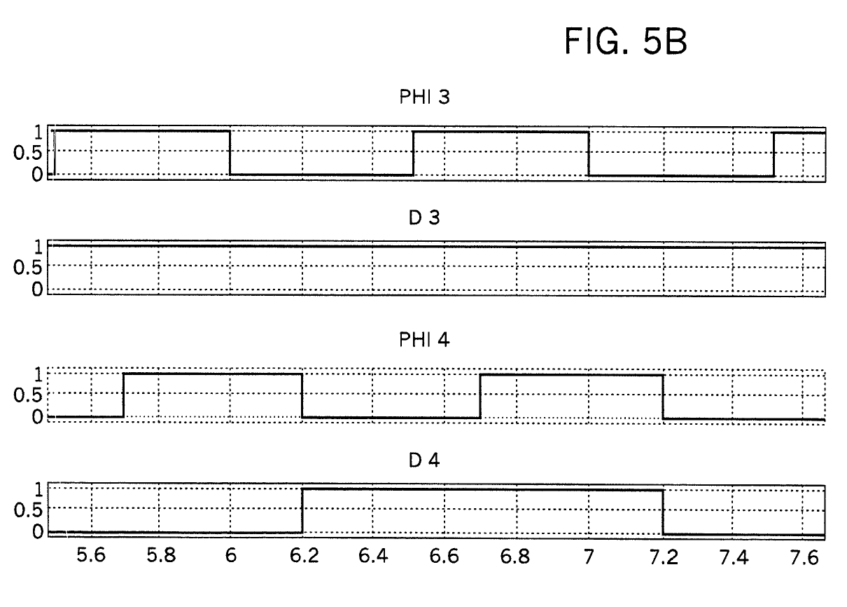

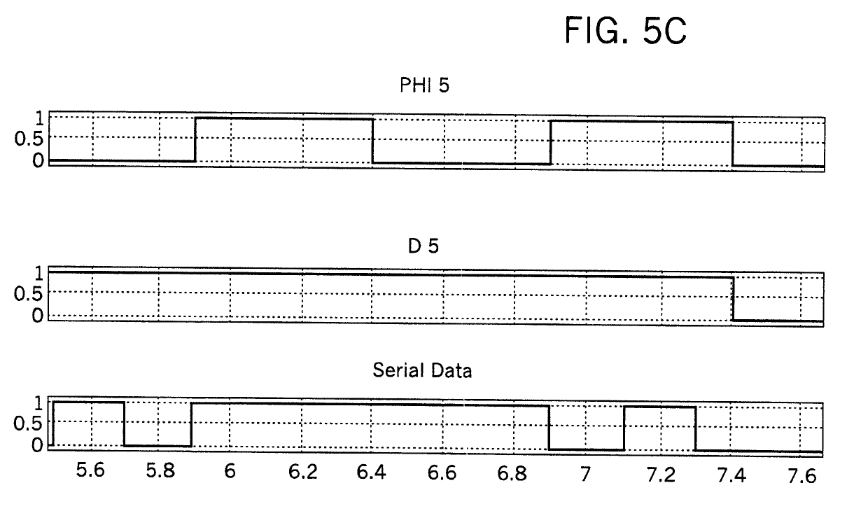

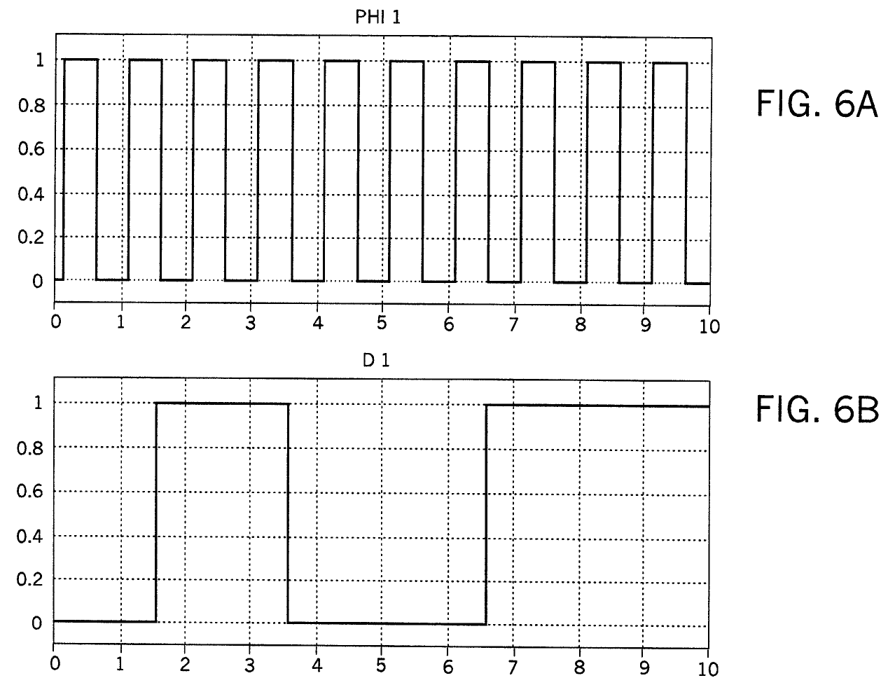

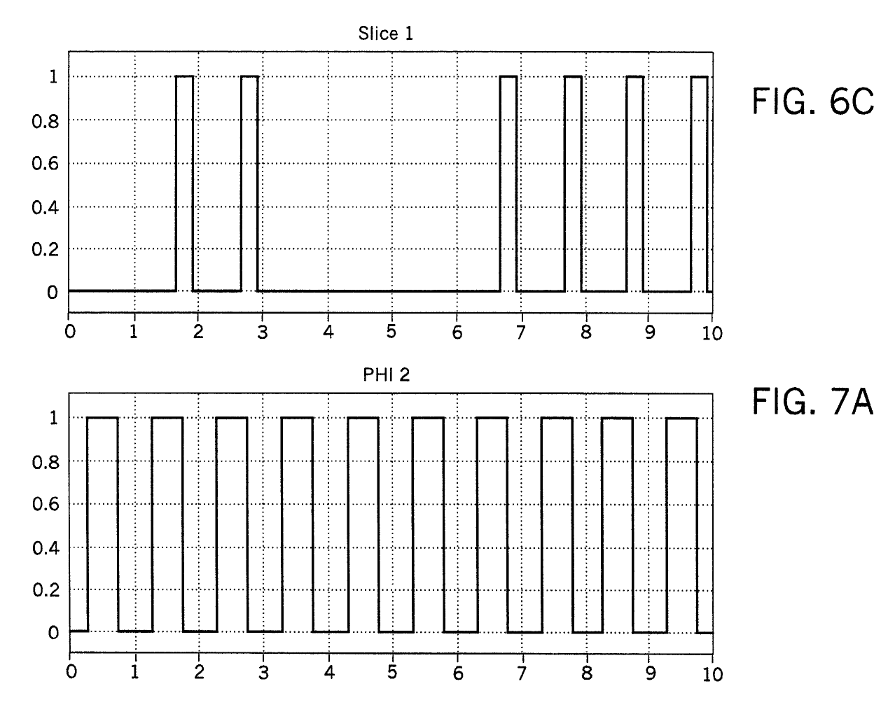

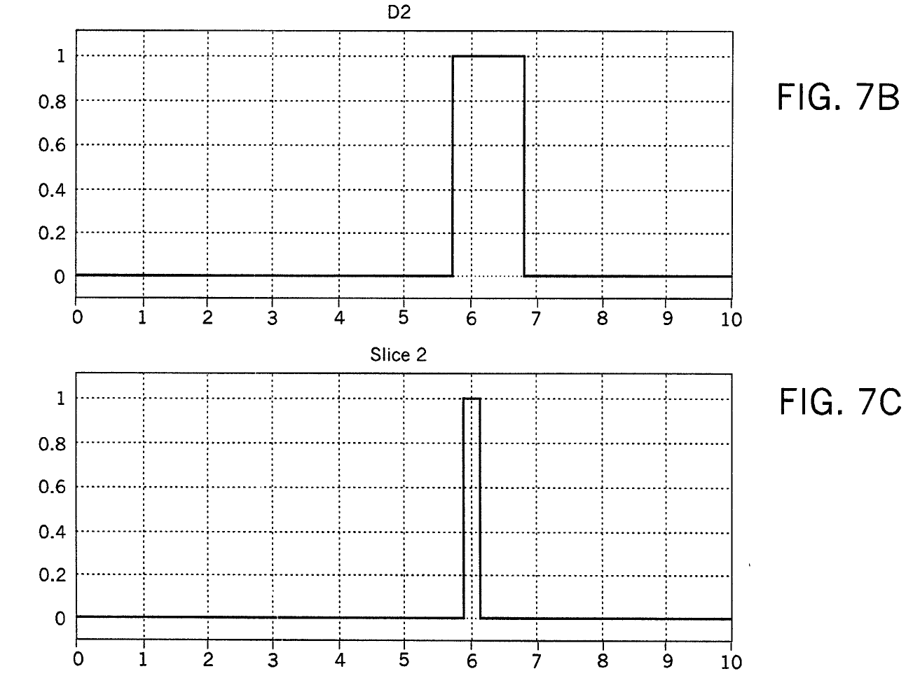

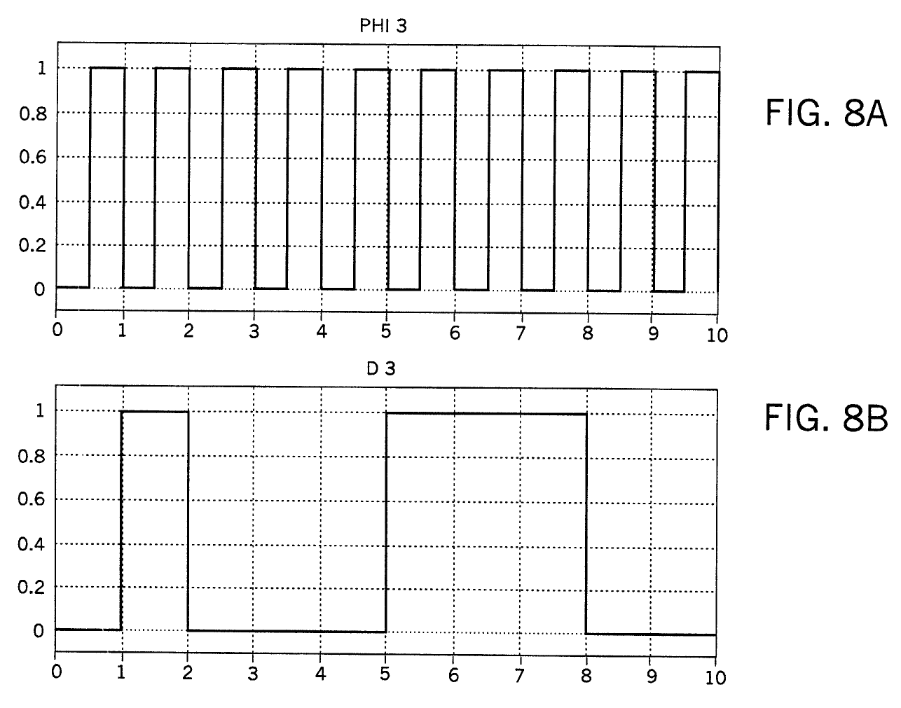

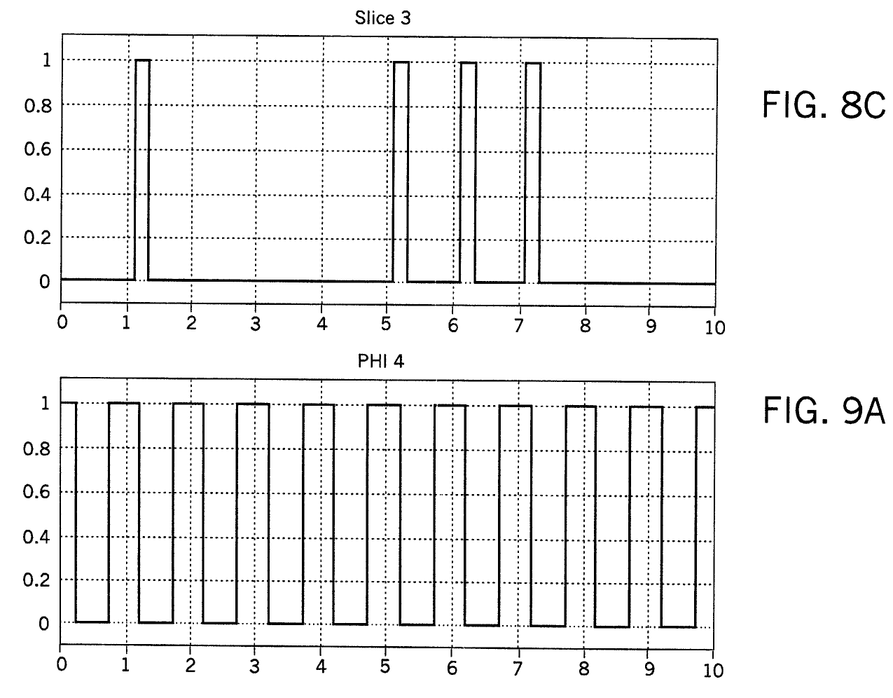

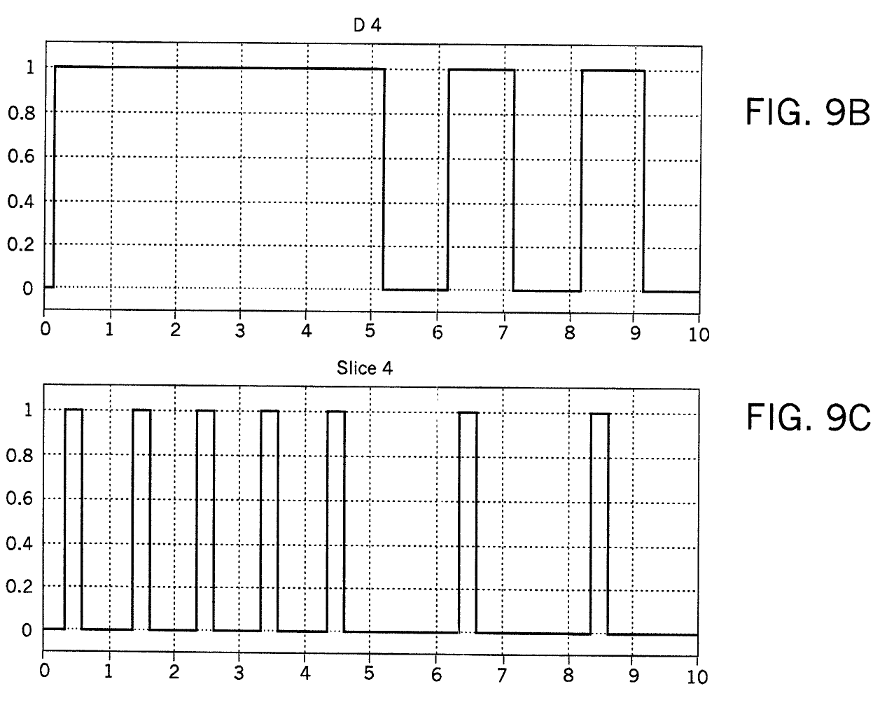

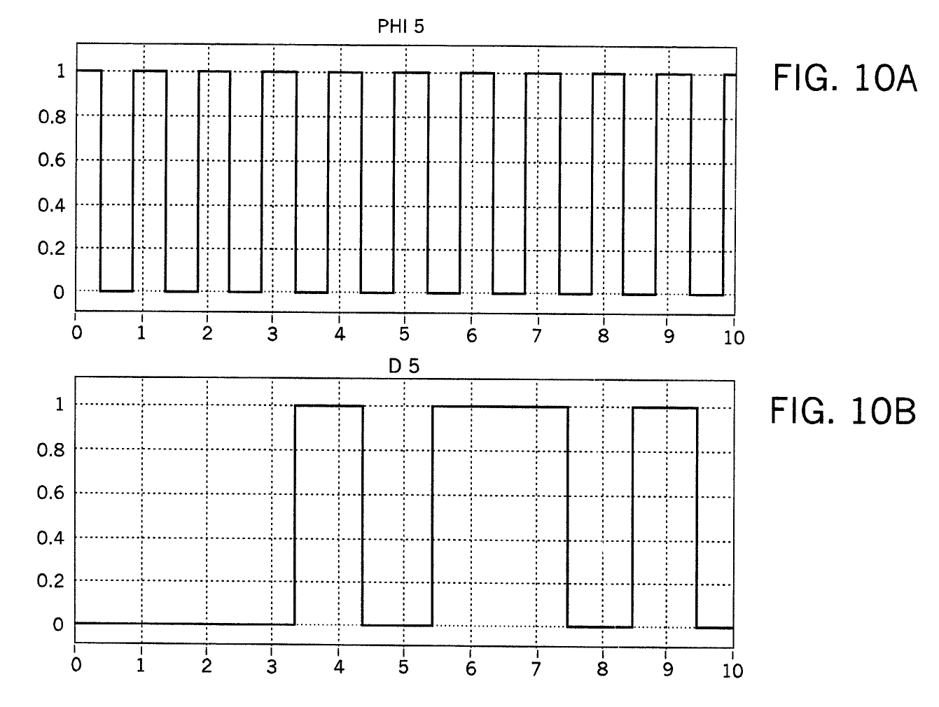

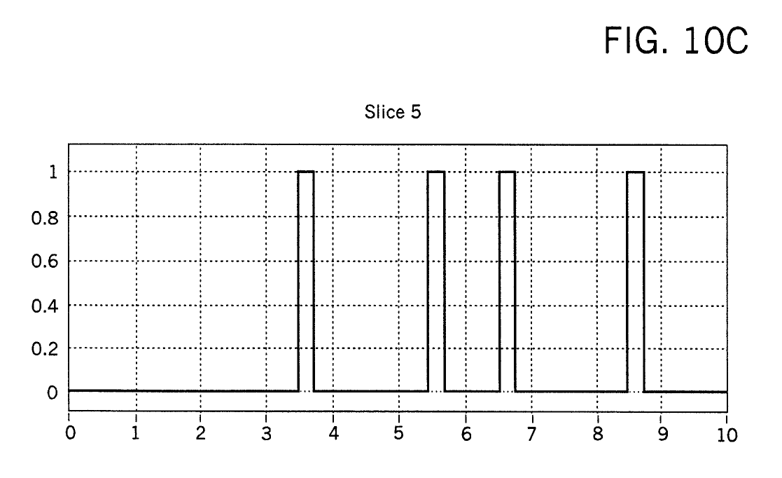

The operation of each subsystem 301 may be understood by referring to FIGS. 5A-C, 6A-C, 7A-C, 8A-C, 9A-C and 10A-C. FIGS. 5A-C illustrate a timing diagram of each phase, e.g., PHI1-5, of clock 202 and each bit, e.g., D1-D5, of parallel data 201. FIG. 5C further illustrates the serial data produced as output of OR gate 302. FIGS. 6A-C illustrate a timing diagram of PHI1 of clock 202, D1 of parallel data 201 and slice 1 which refers to the slice(s) of serial data produce by subsystem 301A. FIGS. 7A-C illustrate a timing diagram of PHI2 of clock 202, D2 of parallel data 201 and slice 2 which refers to the slice(s) of serial data produce by subsystem 301B. FIGS. 8A-C illustrate a timing diagram of PHI3 of clock 202, D3 of parallel data 201 and slice 3 which refers to the slice(s) of serial data produce by subsystem 301 C. FIGS. 9A-C illustrate a timing diagram of PHI4 of clock 202, D4 of parallel data 201 and slice 4 which refers to the slice(s) of serial data produce by subsystem 301D. FIGS. 10A-C illustrate a timing diagram of PHI5 of clock 202, D5 of parallel data 201 and slice 5 which refers to the slice(s) of serial data produce by subsystem 301E.

As stated above, each subsystem 301 may generate slice(s) of the serial data. A slice may refer to a piece or a segment of serial data. Each subsystem 301 may generate slice(s) based on performing a logical AND operation on a particular bit in parallel data 201 as well as on three of the five phases of clock 202. For example, subsystem 301A may generate one or more slices of the serial data where each slice generated by subsystem 301A has the notation of “slice 1”. Subsystem 301A may generate one or more slices of the serial data based on the logical AND operation on PHI4, D1, PHI3 and PHI5′ where the ′ after PHI5 indicates that the logical state of PHI5 has been inverted. The output, e.g., slice 1, of subsystem 301A may become high when the logical state of PHI4, D1 are PHI3 high and the logical state of PHI5 is low. Referring to FIGS. 5A-C, the logical states of PHI4, D1 and PHI3 are high and the logical state of PHI5 is low from 6.7 to 6.9. Referring to FIG. 6C, slice 1 is consequently high from 6.7 to 6.9. It is noted that slice 1 is high at other points in time in FIG. 6C for similar reasons, i.e., when the logical states of PHI4, D1 and PHI3 are high and the logical state of PHI5 is low, which may not be illustrated in FIGS. 5A-C. It is further noted that an artisan of ordinary skill would understand when slice 1 became high at other points in time not illustrated in FIGS. 5A-C.

Subsystem 301B may generate one or more slices of the serial data where each slice generated by subsystem 301B has the notation of “slice 2”. Subsystem 301B may generate one or more slices of the serial data based on the logical AND operation on PHI5, D2, PHI4 and PHI1′ where the ′ after PHI1 indicates that the logical state of PHI1 has been inverted. The output, e.g., slice 2, of subsystem 301B may become high when the logical state of PHI5, D2 are PHI4 high and the logical state of PHI1 is low. For example, referring to FIGS. 5A-C, the logical states of PHI5, D2 and PHI4 are high and the logical state of PHI1 is low from 5.9 to 6.1. Referring to FIG. 7C, slice 2 is consequently high from 5.9 to 6.1. It is noted that slice 2 is high at other points in time in FIG. 7C for similar reasons, i.e., when the logical states of PHI5, D2 and PHI4 are high and the logical state of PHI1 is low, which may not be illustrated in FIGS. 5A-C. It is further noted that an artisan of ordinary skill would understand when slice 2 became high at other points in time not illustrated in FIGS. 5A-C.

Subsystem 301C may generate one or more slices of the serial data where each slice generated by subsystem 301C has the notation of “slice 3”. Subsystem 301C may generate one or more slices of the serial data based on the logical AND operation on PHI1, D3, PHI5 and PHI2′ where the ′ after PHI2 indicates that the logical state of PHI2 has been inverted. The output, e.g., slice 3, of subsystem 301C may become high when the logical state of PHI1, D3 are PHI5 high and the logical state of PHI2 is low. For example, referring to FIGS. 5A-C, the logical states of PHI1, D3 and PHI5 are high and the logical state of PHI2 is low from 6.1 to 6.3. Referring to FIG. 8C, slice 3 is consequently high from 6.1 to 6.3. It is noted that slice 3 is high at other points in time in FIG. 8C for similar reasons, i.e., when the logical states of PHI1, D3 and PHI5 are high and the logical state of PHI2 is low, which may not be illustrated in FIGS. 5A-C. It is further noted that an artisan of ordinary skill would understand when slice 3 became high at other points in time not illustrated in FIGS. 5A-C.

Subsystem 301D may generate one or more slices of the serial data where each slice generated by subsystem 301D has the notation of “slice 4”. Subsystem 301D may generate one or more slices of the serial data based on the logical AND operation on PHI2, D4, PHI1 and PHI3′ where the ′ after PHI3 indicates that the logical state of PHI3 has been inverted. The output, e.g., slice 4, of subsystem 301D may become high when the logical state of PHI2, D4 are PHI1 high and the logical state of PHI3 is low. For example, referring to FIGS. 5A-C, the logical states of PHI2, D4 and PHI1 are high and the logical state of PHI3 is low from 6.3 to 6.5. Referring to FIG. 9C, slice 4 is consequently high from 6.3 to 6.5. It is noted that slice 4 is high at other points in time in FIG. 9C for similar reasons, i.e., when the logical states of PHI2, D4 and PHI1 are high and the logical state of PHI3 is low, which may not be illustrated in FIGS. 5A-C. It is further noted that an artisan of ordinary skill would understand when slice 4 became high at other points in time not illustrated in FIGS. 5A-C.

Subsystem 301E may generate one or more slices of the serial data where each slice generated by subsystem 301E has the notation of “slice 5”. Subsystem 301E may generate one or more slices of the serial data based on the logical AND operation on PHI3, D5, PHI2 and PHI4′ where the ′ after PHI4 indicates that the logical state of PHI4 has been inverted. The output, e.g., slice 5, of subsystem 301E may become high when the logical state of PHI3, D5 are PHI2 high and the logical state of PHI4 is low. For example, referring to FIGS. 5A-C, the logical states of PHI3, D5 and PHI2 are high and the logical state of PHI4 is low from 6.5 to 6.7. Referring to FIG. 10C, slice 5 is consequently high from 6.5 to 6.7. It is noted that slice 5 is high at other points in time in FIG. 10C for similar reasons, i.e., when the logical states of PHI3, D5 and PHI2 are high and the logical state of PHI4 is low, which may not be illustrated in FIGS. 5A-C. It is further noted that an artisan of ordinary skill would understand when slice 5 became high at other points in time not illustrated in FIGS. 5A-C.

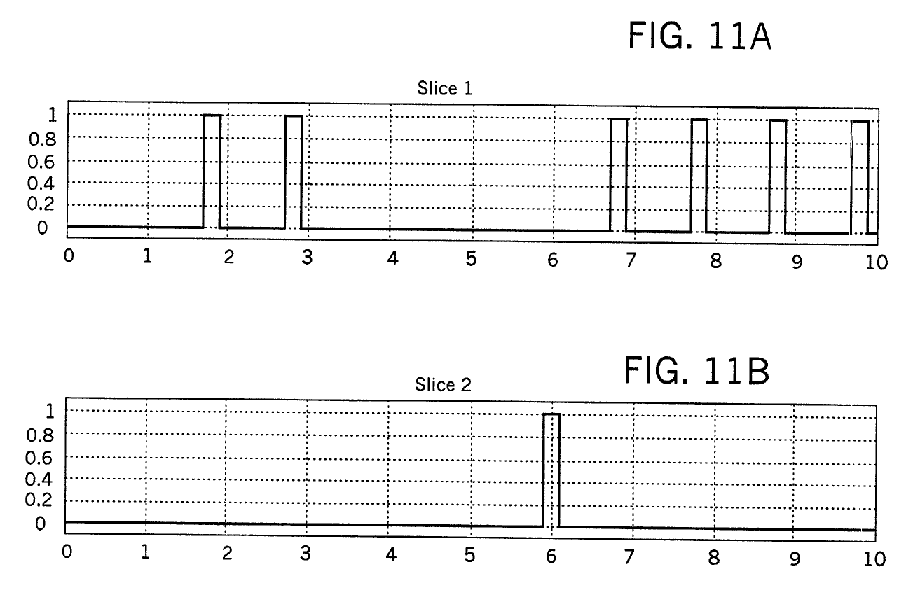

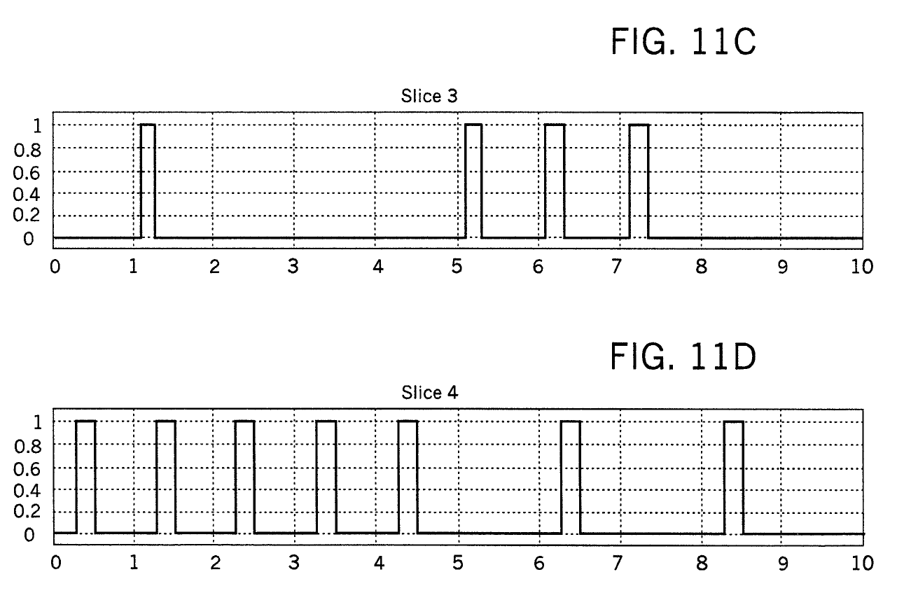

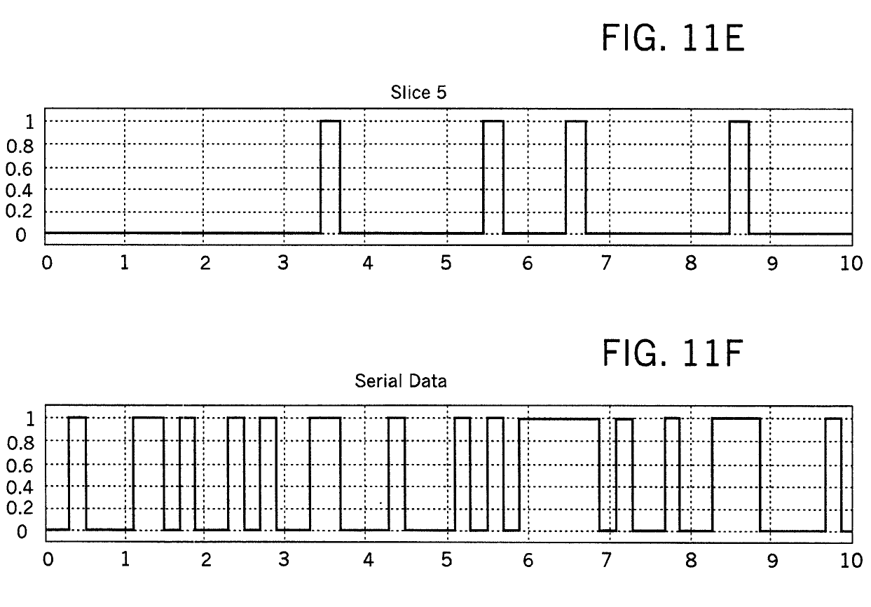

As stated above, OR gate 302 performs the logical OR operation on the plurality of slices, e.g., slice 1-5, outputted by subsystems 301, e.g., subsystem 301A-E. FIGS. 11A-F illustrates a timing diagram of the plurality of slices, e.g., outputted by subsystems 301, subsystem 301A-E, as well as the resulting serial data produced by OR gate 302 performing the logical OR operation on the plurality of slices, e.g., slices 1-5.

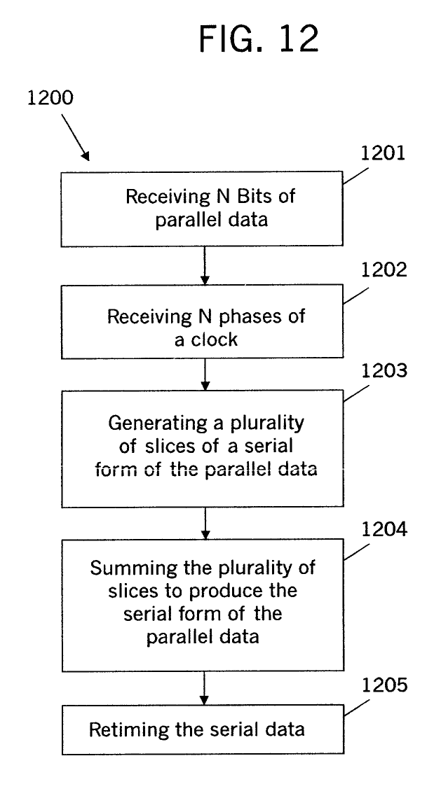

FIG. 12—Method for Serializing Parallel Data

FIG. 12 illustrates a flowchart of one embodiment of the present invention of a method 1200 for serializing parallel data. As stated in the Background Information section, a serializer may be used in a communication system to convert parallel data to a serial form. Typically, a serializer converts the parallel data to a serial form using a phase-locked loop oscillator operating at the transmission rate, i.e., data rate. By the phase-locked loop oscillator operating at a frequency equivalent to the transmission rate, i.e., data rate, a significant amount of power may be used. It would therefore be desirable to serialize data by using multiple phases of a clock operating at a frequency lower than the data rate thereby saving power. Method 1200 is a method for serializing parallel data using multiple phases of a clock operating at a frequency lower than the data rate.

In step 1201, serializer 203 receives N bits, e.g., five bits, of parallel data 201. In step 1202, serializer 203 receives M phases, e.g., five phases, of phase clock 202. In one embodiment, serializer 203 receives the N bits, e.g., five bits, of parallel data 201 coincident with the M phases, e.g., five phases, of clock 202. In one embodiment, the number of phases of clock 202 is the same number as the number of bits in parallel data 201 when one edge of the phases of clock 202 is used to convert parallel data 201 into a serial form. When the number of phases of clock 202 is the same number as the number of bits in parallel data 201, clock 202 operates at a frequency of (1/N) times the serial data rate thereby saving power by operating at a frequency lower than the serial data rate. In another embodiment, the number of phases of clock 202 is one half the number of bits in parallel data 201 when both edges of the phases of clock 202 are used to convert parallel data 201 into a serial form. When the number of phases of clock 202 is one half the number of bits in parallel data 201, clock 202 operates at a frequency of (1/2N) times the serial data rate. It is noted that serializer 203 may receive any number of bits of parallel data 201 and therefore any number of phases of clock 202.

Serializer 203 may be configured to convert N bits, e.g., five bits, of parallel data 201 to a serial form using M phases, e.g., five phases, of clock 202 by generating a plurality of slices where each slice is a section or segment of serial data in step 1203. Referring to FIG. 3, Serializer 203 may comprise a plurality of subsystems 301, e.g., subsystems 301A-E, configured to generate a plurality of “slices” of serial data.

As stated above, each subsystem 301 may be configured to generate one or more slices of serial data by logically ANDing three phases of clock 202 and a particular bit in parallel data 201 as illustrated in FIG. 4. Referring to FIG. 4, subsystem 301 may comprise a logical AND gate 406 that performs the AND operation on a particular bit in parallel data 201 as well as on three of the five phases of clock 202 that are inputted to subsystem 301, e.g., PHI TOP 401, PHI MID 403, PHI BOT 404. The logical state of the phase of clock 202 inputted to PHI BOT 404 of subsystem 301 may be inverted by a logical NOT gate 405. The output of each subsystem 301 is one or more slices of serial data.

In step 1204, serializer 203 may be configured to perform a logical OR operation on the plurality of slices, e.g., slice 1-5, outputted by subsystems 301, e.g., subsystems 301A-E. That is, the plurality of slices, e.g., slice 1-5, may be combined, i.e., summed, to produce a serial form of parallel data 201 received by serializer 203. In one embodiment, serializer 203 may comprise a logical OR gate 302 configured to perform the logical OR operation on each “slice” of serial data generated by each subsystem 301.

In step 1205, it may be desirable but not necessary for timing uncertainties, i.e., jitter, exhibited by the serial form of parallel data 201 generated by serializer 203 to be diminished by retiming mechanism 204 retiming the serial form of parallel data 201. Retiming mechanism 204 may be configured to sample the serial data signal at points in time when the serial data signal is not likely to experience timing uncertainties, e.g., sampling during the middle of a period of the serial data signal. The output of retiming mechanism 204 is the retimed data where the retimed data is the data after sampling the serial data signal at points in time when the serial data signal is not likely to experience jitter.

Although the system, transmitter and method are described in connection with several embodiments, it is not intended to be limited to the specific forms set forth herein, but on the contrary, it is intended to cover such alternatives, modifications, and equivalents, as can be reasonably included within the spirit and scope of the invention as defined by the appended claims. It is noted that the headings are used only for organizational purposes and not meant to limit the scope of the description or claims.

1. A system comprising:
a transmission medium;
a receiver coupled to said transmission medium, wherein said receiver is configured to receive data in a serial form; and
a transmitter coupled to said transmission medium having circuitry for receiving parallel data of N bits per cycle at a parallel clock rate, circuitry for receiving M phases of a phase clock operating at a frequency below a serial clock rate, circuitry for generating a plurality of slices of said serial form of said parallel data, and circuitry for combining said plurality of slices to produce said serial form of said parallel data for transmission at said serial clock rate.

2. The system as recited in claim 1, wherein said transmitter comprises a serializer configured to receive said N bits of said parallel data and said M phases of said phase clock.

3. The system as recited in claim 2, wherein said serializer comprises one or more subsystems configured to generate said plurality of slices of said serial form of said parallel data.

4. The system as recited in claim 3, wherein each of said one or more subsystems comprises a first logical unit configured to perform a logical AND operation on a portion of said M phases of said phase clock with a particular bit of said parallel data.

5. The system as recited in claim 4, wherein said serializer further comprises a second logical unit configured to perform a logical OR operation on said plurality of slices of said serial form of said parallel data generated by said one or more subsystems.

6. The system as recited in claim 5, wherein said second logical unit produces data in said serial form.

7. The system as recited in claim 1, wherein said phase clock operates at a frequency of 1/N of a data rate of said serial data when one edge of said phases of said phase clock is used to convert said parallel data to said serial data.

8. The system as recited in claim 1, wherein said phase clock operates at a frequency of 1/(2*N) of a data rate of said serial data when both edges of said phases of said phase clock are used to convert said parallel data to said serial data.

9. A transmitter comprising:
a first input configured to receive parallel data;
a second input configured to receive phases of a clock;
a serializer coupled to said first and said second input, wherein said serializer is configured to generate a plurality of slices of a serial form of said parallel data in response to said phases of said clock, wherein said serializer is configured to combine said plurality of slices to produce said serial form of said parallel data.

10. The transmitter as recited in claim 9, wherein said parallel data has N bits, wherein said phases of said clock comprises M phases.

11. The transmitter as recited in claim 10, wherein said serializer comprises one or more subsystems configured to generate said plurality of slices of said serial form of said parallel data.

12. The transmitter as recited in claim 11, wherein each of said one or more subsystems comprises a first logical unit configured to perform a logical AND operation on a portion of said M phases of said clock with a particular bit of said parallel data.

13. The transmitter as recited in claim 12, wherein said serializer further comprises a second logical unit configured to perform a logical OR operation on said plurality of slices of said serial form of said parallel data generated by said one or more subsystems.

14. The transmitter as recited in claim 13, wherein said second logical unit produces data in said serial form.

15. The transmitter as recited in claim 10, wherein said clock operates at a frequency of 1/N of a data rate of said serial data when one edge of said phases of said clock is used to convert said parallel data to said serial data.

16. The system as recited in claim 10, wherein said clock operates at a frequency of 1/(2*N) of a data rate of said serial data when both edges of said phases of said clock are used to convert said parallel data to said serial data.

17. The transmitter as recited in claim 9 further comprising:
a retiming mechanism configured to retime said serial form of said parallel data.

18. A method for serializing parallel data comprising the steps of:
receiving N bits of parallel data;
generating a plurality of slices of a serial form of said parallel data; and
combining said plurality of slices to produce said serial form of said parallel data.

19. The method as recited in claim 18 further comprising the step of:
receiving M phases of a clock, wherein said plurality of slices are generated in response to said M phases of said clock.

20. The method as recited in claim 19, wherein said clock operates at a frequency of 1/N of a data rate of said serial data when one edge of said phases of said clock is used to convert said parallel data to said serial data.

21. The system as recited in claim 19, wherein said clock operates at a frequency of 1/(2*N) of a data rate of said serial data when both edges of said phases of said clock are used to convert said parallel data to said serial data.

22. The method as recited in claim 19, wherein said plurality of slices of said serial form of said parallel data are generated by logically ANDing a subset of said M phases of said clock and a particular bit of said parallel data.

23. A transmitter comprising:
circuitry for receiving parallel data;
circuitry for receiving phases of a clock;
one or more subsystems for ANDing a subset of said phases of said clock and a particular bit of said parallel data to produce a plurality of slices of a serial form of said parallel data; and
an OR gate for ORing said plurality of slices of said serial form of said parallel data to produce data in said serial form.
